(19) United States
(12) Patent Application Publication
(10) Pub. No.: US 2006/0267055 A1
(43) Pub. Date: Nov. 30, 2006

(54) Ferroelectric polymer memory device having pyramidal electrode layer and method of forming same

(75) Inventors: Mani Rahnama, Beaverton, OR (US); Gerald W. Palmrose, Tigard, OR (US); Jeffrey T. West, Tigard, OR (US); Ebrahim Andideh, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/137,965

(22) Filed: May 25, 2005

(51) Int. Cl. H01L 27/108; H01L 21/8239

(52) U.S. Cl. 257/295; 438/3; 438/240

(57) ABSTRACT

A ferroelectric polymer memory device and a method of providing an electrode layer of the device. The device comprises: a substrate; a plurality of electrode layers including a first electrode layer disposed on the substrate and a second electrode layer extending at an angle with respect to the first electrode layer in a longitudinal direction thereof; a ferroelectric layer disposed between the first electrode layer and the second electrode layer to form memory cells; a ILD layer disposed on the second electrode layer; wherein at least one of the plurality of electrode layers exhibits a pyramidal profile in a widthwise cross-section thereof.

### FIELD

Embodiments of the present invention relate generally to the field of integrated circuit device manufacture and more particularly to the manufacture of memory devices.

### BACKGROUND

Ferroelectric devices such as ferroelectric polymer memory devices (FPMD's) may comprise one or more layers of ferroelectric material sandwiched between layers of electrodes. Methods of formation of devices such as ferroelectric polymer memory devices may vary, but one method may comprise depositing a layer of ferroelectric polymer on a first electrode layer, and then depositing and patterning a second electrode layer on a substantial portion of the ferroelectric polymer layer.

Disadvantageously, prior art methods produce FPMD profiles with increased topographies of the polymer layer and thus undesirable levels of non-planarity which limit the patterning process as the number of layers of the FPMD's is to increase. In addition, prior art FPMD profiles present voids between the polymer and the associated electrodes which can lead to undesirable delamination and electromigration within the FPMD. Moreover, FPMD's made according to prior art methods are limited in their line thicknesses (that is, in the thickness of their top and bottom electrodes as seen in top/bottom plan view) in the interest of avoiding shorts between adjacent lines, thus compromising polarization density and signal strength.

A need, therefore, exists for an improved method of forming a ferroelectric polymer memory device that addresses at least some of these concerns.

### BRIEF DESCRIPTION OF THE DRAWINGS

Embodiments of the invention are illustrated by way of example and not by way of limitation in the figures of the accompanying drawings, in which the like references indicate similar elements and in which:

FIG. 1 illustrates a cross sectional view of a portion of a FPMD according to the prior art;

FIG. 2 illustrates a cross sectional view of a portion of a FPMD according to one embodiment;

FIG. 3 is a schematic top plan view of two electrode layers of a FPMD according to the prior art;

FIG. 4 is a schematic top plan view of a two electrode layers of a FPMD according to an embodiment;

FIG. 5 is a plot of polarization density distribution versus polarization density for the memory cells of FIGS. 3 and 4;

FIG. 6 is a schematic top plan view of a plurality of first and second electrode layers of a FPMD according to one embodiment;

FIG. 7 is a cross sectional view of an etching arrangement prior to beginning a three stage etch process according to an embodiment;

FIGS. 8a-8c are views similar to FIG. 7 depicting the three stage etch process according to an embodiment; and

FIG. 9 is a schematic view of a system incorporating a FPMD made according to an embodiment of the present invention.

### DETAILED DESCRIPTION

A ferroelectric polymer memory device having at least one pyramidal electrode layer, a method of forming the pyramidal electrode layer, and a system incorporating the ferroelectric polymer memory device are disclosed herein.

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention, however, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

In addition, although some of the embodiments of the present invention described below refer to layers “formed on” another layer, embodiments of the present invention are not so limited, and pertain to the described configurations whether or not the layers are “formed on” other layer or merely “disposed on” other layers. In addition, as used herein, a layer “disposed on” another layer does not necessarily mean that the layer is directly disposed on the other layer, although it could.

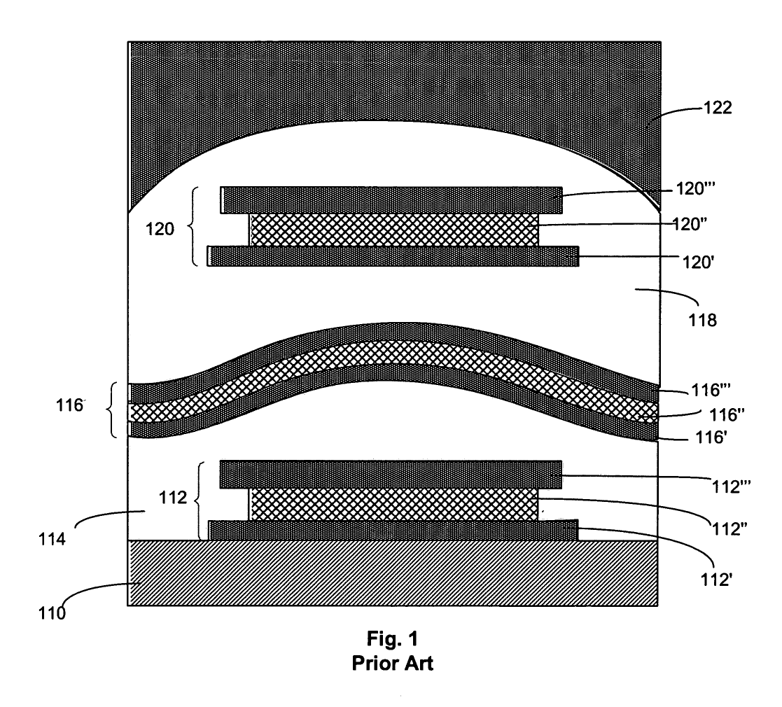

Referring now to FIG. 1 where like reference numerals denote like elements, a side-elevational view of a portion of a FPMD is shown according to the prior art. As seen in FIG. 1, a cross-section of part of a conventional multilayer or stacked FPMD 100 is shown. The stacked FPMD 100 includes electrode layers alternating with layers of ferroelectric material, and may include a substrate 110, such as, for example, an insulating layer comprised of SiO₂, and a first electrode layer 112, which may comprise a plurality of electrode sublayers including first electrode sublayer 112′, second electrode sublayer 112″ and third electrode sublayer 112′″. A first ferroelectric layer 114 is formed on the substrate 110 and first electrode layer 112. The ferroelectric layer 114 may be made of polymer and has the property of spontaneous electric polarization that can be reversed by application of an electric field. A second electrode layer 116 is formed on the top surface of layer 114, again comprising a plurality of electrode sublayers including first electrode sublayer 116′, second electrode sublayer 116″ and third electrode sublayer 116′″. A second ferroelectric layer 118 is formed on the second electrode layer 116 as shown. Within the second ferroelectric layer 118 is a third electrode layer 120 which again comprises a plurality of electrode sublayers including first electrode sublayer 120′, second electrode sublayer 120″ and third electrode sublayer 120′″. In this embodiment of a well-known memory device, substrate 110 may comprise a substrate of CMOS (complimentary metal oxide semiconductor), for example. First electrode layer 112 may be formed on the substrate by a deposition process such as physical vapor deposition (PVD), for example, and may be patterned by use of a photolithography and etch process, for example. A deposition process such as spin deposition may be used to deposit the ferroelectric layers 114 and 118. An ILD layer 122, such as, for example, a layer made of SiH₄based low temperature thermal oxide, or LTO, may be used above second ferroelectric layer 118 as shown. As is well known, each volume of ferroelectric material disposed between corresponding intersecting pairs of superimposed electrodes defines a polarization region and therefore a memory cell of the FPMD 100. According to the prior art, for each of the electrode layers shown, the first sublayer may be made of Ti or TiN and be formed using either evaporation or sputter deposition, the second sublayer may be made of Al and be formed using either evaporation or sputter deposition, and the third sublayer may be made of Ti or TiN and be formed using either evaporation or sputter deposition. The function of having multiple layered electrodes is to minimize the resistance of the electrodes (this function being fulfilled for example by the aluminum sublayer) and to minimize interlayer reactions (this function being fulfilled for example by the Ti/TiN sublayers). Some other possible materials for the electrodes sublayers include Ta/TaN and TiO₂ as a replacement for Ti/TiN. A totally different electrode could further be made with noble metals without the used of reaction barrier layers, such as Ti/TiN or Ta/TaN Typically, the first sublayer may have a thickness ranging from about 100 Angstroms to about 200 Angstroms, the second sublayer may have a thickness ranging from about 200 Angstroms to about 600 Angstroms, and the third sublayer may have a thickness ranging from about 100 Angstroms to about 200 Angstroms. As suggested in FIG. 1, electrode layers 112, 116 and 120 according to the prior art present respective undercuts U112, U116 and U120 in the depicted profiles, the undercuts, as best seen in the widthwise cross-sectional profiles of electrode layers 112 and 120, being defined by the undersides of edges of the topmost first electrode sublayers 112′, 116′ and 120′ as well as by the sides of the second electrode sublayers 112″, 116″ and 120″, respectively.

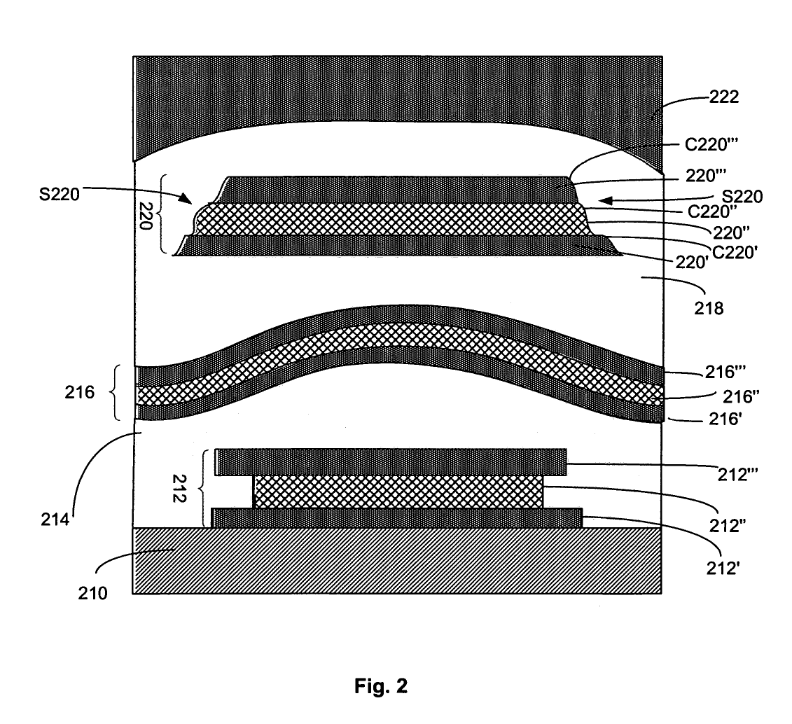

Referring now to FIG. 2, a part of a FPMD is shown comparable to the FPMD of FIG. 1, but in accordance with one embodiment of the present invention. The stacked FPMD 200 according to an embodiment may include electrode layers alternating with layers of ferroelectric material, and may include a substrate 210, which may be an insulating layer comprised of SiO₂, and a first electrode layer 212, which may comprise a plurality of electrode sublayers including first electrode sublayer 212′, second electrode sublayer 212″ and third electrode sublayer 212′″. A first ferroelectric layer 214 may be formed on the substrate 210 and first electrode layer 212. A second electrode layer 216 may be formed on the top surface of layer 214, again comprising a plurality of electrode sublayers including first electrode sublayer 216′, second electrode sublayer 216″ and third electrode sublayer 216′″. A second ferroelectric layer 218 is formed on the second electrode layer 216 as shown. Within the second ferroelectric layer 218 may be a third electrode layer 220 which again comprises a plurality of electrode sublayers including first electrode sublayer 220′, second electrode sublayer 220″ and third electrode sublayer 220′″. The materials and processes of formation of substrate 210 and ferroelectric layers 214 and 218 may be similar to the materials and processes for forming substrate 110 and ferroelectric layers 114 and 118 as described with respect to FIG. 1 above. Ferroelectric polymer layer 214 may comprise one or more layers of polymer based material, including but not limited to polyvinyl and polyethylene fluorides, polyvinyledene fluoride (PVDF), polyvinyl and polyethylene chlorides, polyacrylonitriles, polyamides, polyfluorides, copolymers thereof, and combinations thereof, although it is important to note that the claimed subject matter is not limited to one or more of the materials listed above. Layer 214 may be deposited by one or more spin deposition processes. As suggested in FIG. 2, electrode layers 216 and 220 may define pyramidal profiles in the depicted views, that is, in their widthwise cross-sections (216 not shown in its widthwise cross section). It is noted that, although the embodiment of FIG. 2 shows the bottom electrode as not having a pyramidal profile, embodiments of the present invention include within their scope an FPMD similar to the FPMD of FIG. 2 having a first electrode layer 212 which also has a pyramidal profile. An ILD layer 222, such as, for example, a layer made of SiH₄based low temperature thermal oxide, or LTO, may be provided on layer 218 as shown.

By “pyramidal profile,” what is meant in the context of the present invention is a generally trapezoidal profile (quadrilateral with two parallel sides) where the two non-parallel sides of the profile, such as, for example, sides S220 of layer 220 shown in FIG. 2, are angled such that one of the non-parallel sides defines an obtuse angle with respect to either one of the parallel sides of the profile, and the other one of the non-parallel sides defines an acute angle with respect to said one of the parallel sides. Embodiments of the present invention include within their scope the provision of pyramidal electrode profiles for at least one and at most all of the electrode layers of an FPMD. In the embodiment of FIG. 2, only two (216, 220) of the shown three electrode layers (212, 216, 220) display a pyramidal profile. Additionally, in the context of the present invention, it is not necessarily meant that the sides of each pyramidal electron layer as seen in widthwise cross section, such as layers 216 and 220, should present straight profiles, although the present invention would include such a profile within its scope. Rather, embodiments of the present invention include within their ambit sides of electrode layers as seen in a widthwise cross-sectional profile that, although not straight, present a general sloping direction, the direction being as defined with respect to pyramidal profile” above. It is further noted that a “pyramidal profile” according to embodiments of the present invention may be such as to substantially eliminate undercuts as defined between successive electrode sublayers.

As seen in FIG. 2, a preferred embodiment of the present invention includes a pyramidal electrode profile having sides in its widthwise cross-section, such as sides S220, that include rounded corners for substantially all of the corresponding electrode sublayers. For example, the rounded corners of each of sublayers 220′, 220″ and 220′″ have been indicated as C220′, C220″ and C220′″ in FIG. 2. By “rounded corner,” what is meant in the context of the present invention is a corner that presents smooth rather than an sharp-edged profile, although it is not necessary according to the present invention that all corners of a given sublayer have rounded corners.

According to an embodiment, not only may FPMD electrodes present a pyramidal profile in their widthwise cross-section, they may also present memory cell areas that are at least about 40% larger than their prior art counterparts formed with the same lithography reticle feature sizes and ferroelectric polymer system. It is to be noted that, according to embodiments of the present invention, it is possible to get significantly larger cell sizes than those of the prior art without making changes to the lithography system being used, such as to the reticle, resist, or lithography equipment in general. Advantageously, should feature sizes shrink, with a corresponding change in the lithography node, a pyramidal profile provided according to embodiments of the present invention would still provide benefits as noted herein. The larger cell sizes achieved according to embodiments of the present invention are a consequence of the pyramidal profiles, generating a corresponding increase in polarization density.

Comparing FIGS. 1 and 2, one can easily appreciate that the polymer layer spun on top of the pyramidal electrode layers has less topography than the polymer layer spun on top of the electrode layers of the prior art. The topography can further be appreciated as having a compounding effect. One of the advantages of FPMD's having pyramidal electrode layers according to embodiments of the present invention is improved gap filling and planarization of the polymer layer. Some of the reasons behind the above, as suggested by a comparison of FIGS. 1 and 2, are (1) that electrode layers occupy a larger percentage of total pitch in the prior art, and, as a result, there is more polymer above the plane of the electrode layers; (2) that the prior art profile shows an undercut which causes voids to be filled by the polymer, while the pyramidal profile does not; and (3) that the pyramidal profile allows the polymer to flow more freely across the electrode surface, in this way improving gap filling and planarization capability.

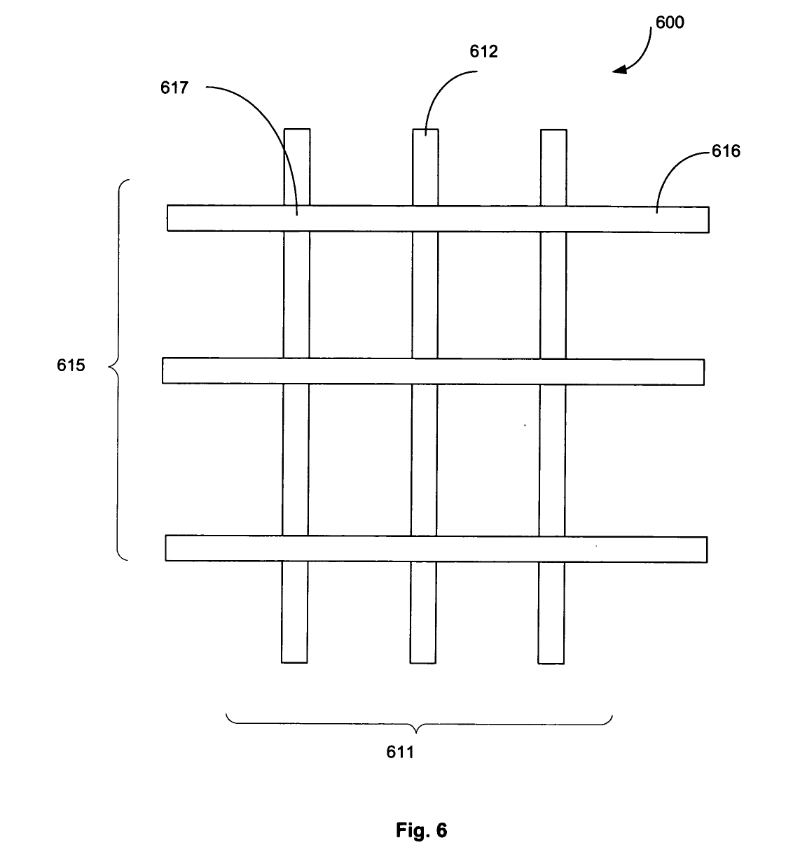

Although device 200 in FIG. 2 is shown to contain only three layers of electrodes, the claimed subject matter is not so limited. A device such as device 200 may be formed to contain multiple layers of electrodes. FPMD's are typically constructed to have 10 to 14 layers of metallization, or more. Additionally, device 200 may contain multiple layers of conductive ferroelectric polymer. Moreover, an FPMD according to the present invention may be formed to contain an array of cross point memory cells 617, as shown in more detail in reference to FIG. 6.

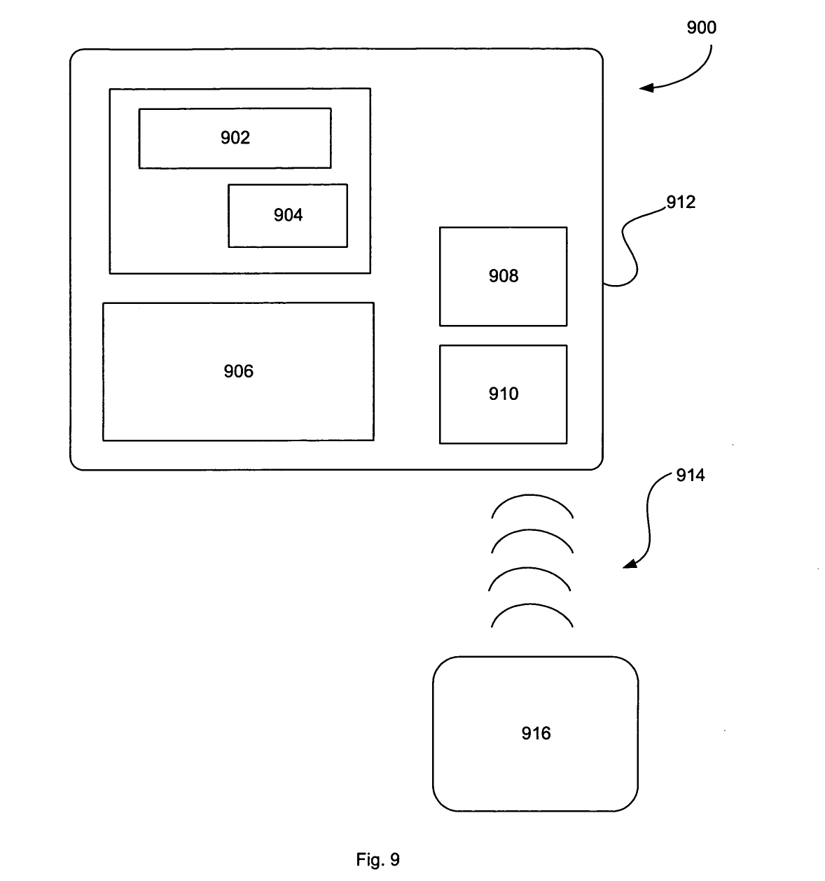

FIG. 6 illustrates a schematic representation of a portion 600 of a polymer memory device, which may incorporate a configuration as described in reference to FIG. 2. As shown in FIG. 6, a first electrode layer 611 may include a plurality of electrodes 612, and a second electrode layer 615 may comprise a plurality of electrodes 616, wherein the electrodes in each respective layer are configured to be substantially parallel to each other, for example. Additionally, the first and second electrode layers may be configured such that they are substantially orthogonal to each other, although the claimed subject matter is not so limited. Additionally, although not shown in detail, the electrode layers may be separated by ferroelectric material, as explained in reference to FIG. 2. The cross over point, or intersection, of a first and second layer electrode may form a memory cell 617. This memory cell may be capable of holding a particular polarization, which may cause the memory cell to hold a representative value such as a ‘1’ or a ‘0’, for example, although the claimed subject matter is not limited to a memory cell that represents only 2 states. Additionally, it is important to note that the memory array portion 600 is for illustrative purposes only, and the claimed subject matter is not limited to a memory array with any particular number of memory cells, or to a device with only two electrode layers. As depicted in FIG. 6, cells 617 are formed by an intersection of first layer electrodes 612 and second layer electrodes 616, which may, for example, be similar to electrodes 212 and 216 described above with reference to FIG. 2. Additionally, a device such as device 200 or 600 may be configured for use in a device such as wireless device 900 of FIG. 9, which will be explained in more detail hereinafter.

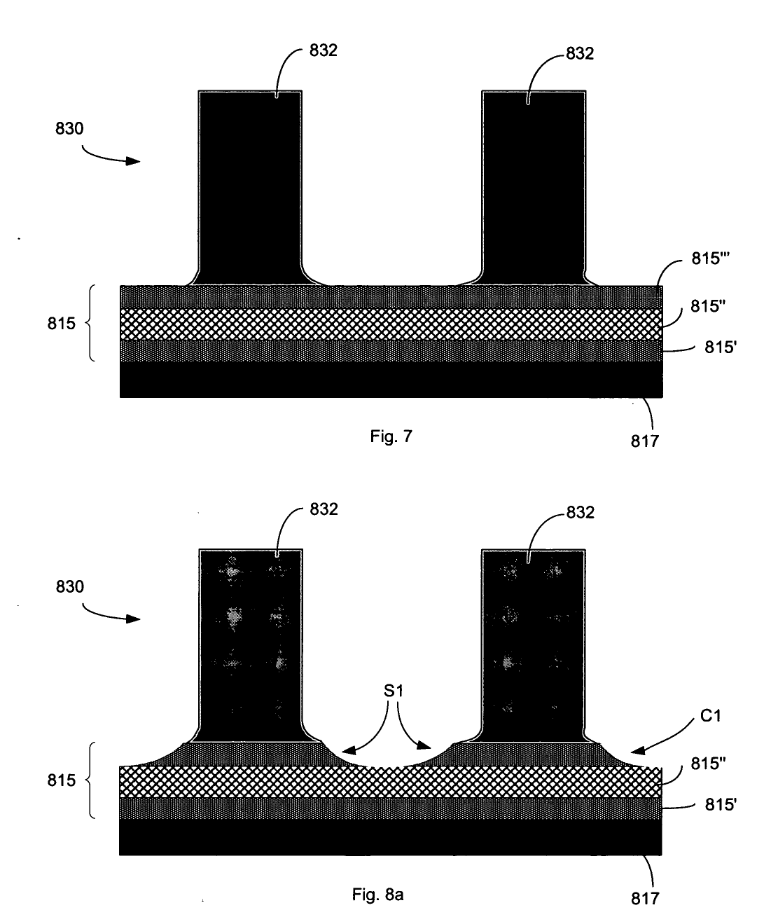

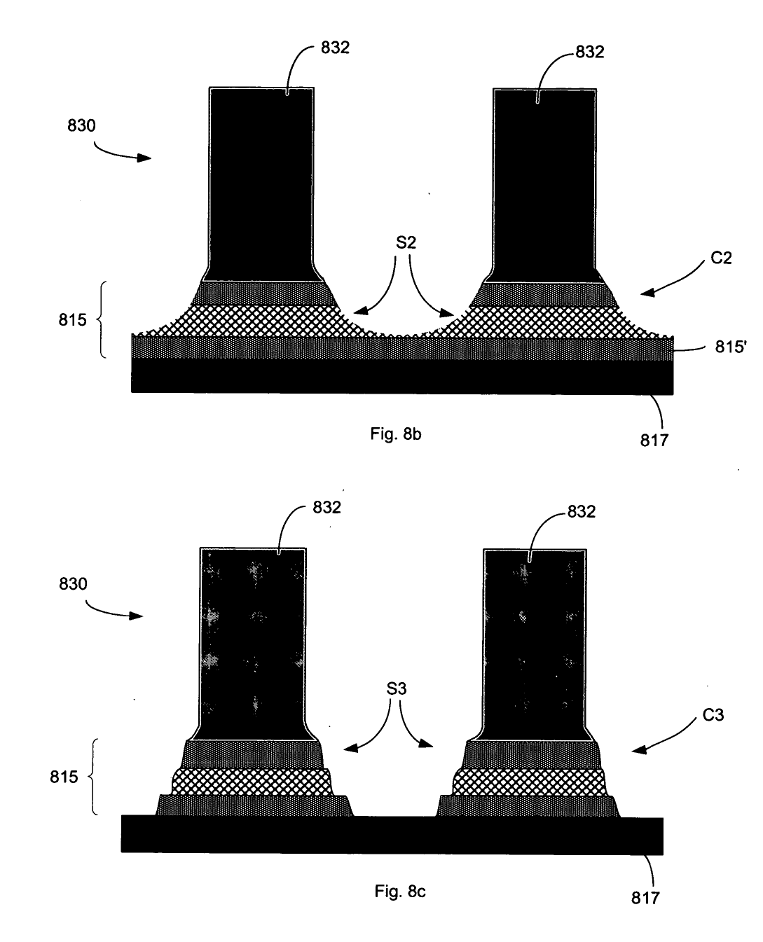

Referring to FIGS. 7 and 8a-8c, an embodiment of a three stage etch process (TSEP) according to the present invention is depicted to achieve a pyramidal electrode profile. By “three stage etch process,” what is meant in the context of the present invention is an etch process that may be characterized by at least three distinct stages, although more stages may be possible. As seen in FIG. 7 and 8a-8c, the TSEP is preceded by the provision of a conductive layer 815 on an initial ferroelectric polymer layer 817. Conductive layer 815 may, for example, be multilayered as shown in FIG. 7, and may include, by way of example, a first conductive sublayer 815′ made of Ti or TiN, a second conductive sublayer 815″ made of Al, and a third conductive sublayer 815′″ made of Ti or TiN. Sublayers 815′, 815″ and 815″ may be formed according to any one of well known methods, such as, for example, those described above with respect to sublayers 116′, 116″ and 116′″, respectively. On the conductive layers 815, a patterned resist layer 830 having resist legs 832 may be deposited by spin coating and developing the resist. Thereafter, based on the resist footing, a pyramidal electrode layer such as, for example, electrode layer 216 or 220 described in relation to FIG. 2, may be etched according to an embodiment of TSEP, as will be described in relation to FIGS. 8a-8c.

Referring next to FIG. 8a, a first stage of forming a pyramidal electrode profile according to one embodiment of the present invention comprises etching the third conductive sublayer 815′″ to achieve a first configuration C1 including sides S1 of the etched sublayer 815′″, the sides S1 being generally sloped from the resist legs toward the second conductive sublayer 815″ in a direction away from the resist legs. According to the first stage, most of the third conductive sublayer 815′″ and some of the second conductive sublayer 815″ may be etched. Thus, some of the material of the third conductive sublayer 815′″ may remain close to the resist legs as shown. Any material removed from the second conductive sublayer 815″, typically up to about 100 Angstroms, would be due to the non-uniformity of the sublayer's thickness. The above configuration may be achieved, by way of example, on a third conductive sublayer made of Ti or TiN, and having a thickness of about 200 Angstroms using an etch recipe including a BCl₃ flow rate between about 30 to about 60 ccm, a Cl₂ flow rate between about 5 to about 20 ccm to prevent corrosion during the post-etch treatment and to passivate the side walls prior to the second stage of the TSEP to be described below, a He flow rate between about 40 to about 100 ccm, at an etch pressure between about 5 to about 10 mTorr, and an RF power between about 120 to about 200 Watts for a duration between about 10 to about 15 seconds with a Mg anode current between about 170 to about 300 mA. Preferably, on the 200 Angstrom sublayer mentioned above, the etch recipe includes, according to a preferred embodiment, a BCl₃ flow rate of about 40 ccm, a Cl₂ flow rate of about 10 ccm, a He flow rate of about 50 ccm, at an etch pressure of about 8 mTorr, and an RF power of about 150 Watts for a duration of about 10 seconds with a Mg anode current of about 200 mA. The first stage in TSEP has as one of its aims to create a slope in the third conductive layer, such as Ti or TiN, while preferably substantially preventing the formation of an undercut and while at the same time allowing corrosion prevention during post etch treatment.

Referring next to FIG. 8b, a second stage of forming a pyramidal electrode profile according to one embodiment of the present invention comprises etching the second conductive sublayer 819″ to achieve a second configuration C2 including sides S2 of the etched sublayer 819″, the sides S2 being generally sloped from the etched third conductive sublayer 819′″ toward the second conductive sublayer 819″ in a direction away from the resist legs. Such a configuration may be achieved on a second conductive sublayer made of Al, for example, and having a thickness of about 400 Angstrom using an etch with a BCl₃ flow rate of about 80 ccm to about 120 ccm, no Cl₂, at an etch pressure between about 5 mTorr to about 10 mTorr, and an RF power between about 150 Watts to about 250 Watts for a duration between about 15 seconds to about 25 seconds setting the Mg anode current between about 170 mA and 300 mA. Preferably, the etch would include a BCl₃ flow rate of about 92 ccm, no Cl₂, at an etch pressure of about 8 mTorr, and an RF power of about 200 Watts for a duration of about 20 seconds setting the Mg anode current at about 200 mA. The relatively high RF power range mentioned above ensures etch directionality and low isotropic behavior. The second stage in TSEP has as one of its aims to create a slope in the second conductive layer, such as Al, while preventing the formation of an undercut as would be the case in the prior art.

Referring now to FIG. 8c, a third stage of forming a pyramidal electrode profile according to one embodiment of the present invention comprises etching the first conductive sublayer 819′ to achieve a third configuration C3 including sides S3 of the etched sublayer 819′, the sides S3 being generally sloped from the etched second conductive sublayer 819″ toward the polymer layer 817 in a direction away from the resist legs. Configuration C3 is further associated with the formation of electrode layers 820 having a pyramidal profile as shown. Configuration C3 may be achieved on a first conductive sublayer made of Ti or TiN, for example, and having a thickness of about 200 Angstroms using an etch with a BCl₃ flow rate between about 30 ccm to about 60 ccm, a Cl₂ flow rate between about 5 ccm to about 20 ccm, a He flow rate between about 40 ccm to about 100 ccm, at an etch pressure between about 5 mTorr to about 10 mTorr, and an RF power between about 50 Watts to about 75 Watts for a duration of about 45 seconds setting the Mg anode current between about 170 mA to about 300 mA. Preferably, the etch has a BCl₃flow rate of about 40 ccm, a Cl₂ flow rate of about 10 ccm, a He flow rate of about 50 ccm, at an etch pressure of about 5 mTorr, and an RF power of about 65 Watts for a duration of about 45 seconds setting the Mg anode current at about 170 mA. The third stage in TSEP has as one of its aims to create a slope in the first conductive layer, such as Ti or TiN, while preventing damage to the underlying polymer layer.

A post-etch treatment (PET) may be performed after the third stage according to an embodiment in order to prevent metal corrosion such as corrosion of a sublayer 815″ when sublayer 815″ is made of aluminum, in the presence of a ferroelectric polymer such as ferroelectric layer 817. The Cl₂ used during etch in the first stage as described above has as one of its aims to make possible the PET described herein. It is noted that the PET would be ineffective if the etch of the first stage described above were a purely BCl₃ etch, as the wafers would likely corrode even if they were washed in situ at a very high temperature, such as a temperature of about 325 degrees Centigrade. PET according to embodiments of the present invention may, by way of example, involve flowing methanol at temperatures below 140 degrees Centigrade over the first configuration C1. Such a process would bleach most of the Cl₂ while passivating the sidewalls of the etched third sublayer 815′″ to prevent humidity from air from interacting with post etch residual chlorine attached to the walls of the sublayer 815′″. The temperature may be kept low during the PET in order to prevent the degradation of the properties of the ferroelectric polymer. PET as part of the etching process of the third conductive sublayer may include a CH₃OH etch at a flow rate up to about 200 ccm, O₂ at a flow rate up to about 1000 ccm, at a pressure of up to about 3 Torr, for a duration between about 50 to about 200 seconds. For example, for the 200 Angstrom Ti or TiN layer mentioned in the paragraph above, and etched as described above, PET may involve flowing methanol at a rate of about 100 ccm, preferably at a rate of about 150 ccm, at a pressure above about 0.5 Torr, and preferably at a pressure of about 0.5 Torr, for a time duration above about 80 seconds, and preferably at a time duration of about 130 seconds.

Variations and optimizations are possible to the above stages according to embodiments of the present invention by varying flow rates and etch times, for example, in order to achieve particular desired results. For example, stage one according to embodiments may be long enough to allow PET to stop corrosion as described above. Stage two may not be so long as to miss the endpoint in stage three. The “endpoint” represents an event that may be determined automatically by measuring plasma emissions (“endpoint trace”) during an etch. The endpoint trace rises and falls during the etch, and may be monitored during stage two to assure that it is not falling at the end of a predetermined duration for state 2. In other words, preferably, a predetermined duration is set for stage 2 such that, at the end of such time period, the endpoint trace is not falling. The endpoint in stage three corresponds to a transition point of the trace in which the second derivative of the trace goes from being negative to being positive, which transition is defined as the endpoint. Stage three thus has an endpoint, and may be continued to allow enough over etch in order to ensure complete clearing of the electrode layer in question in order to prevent line to line shorts.

### EXAMPLE

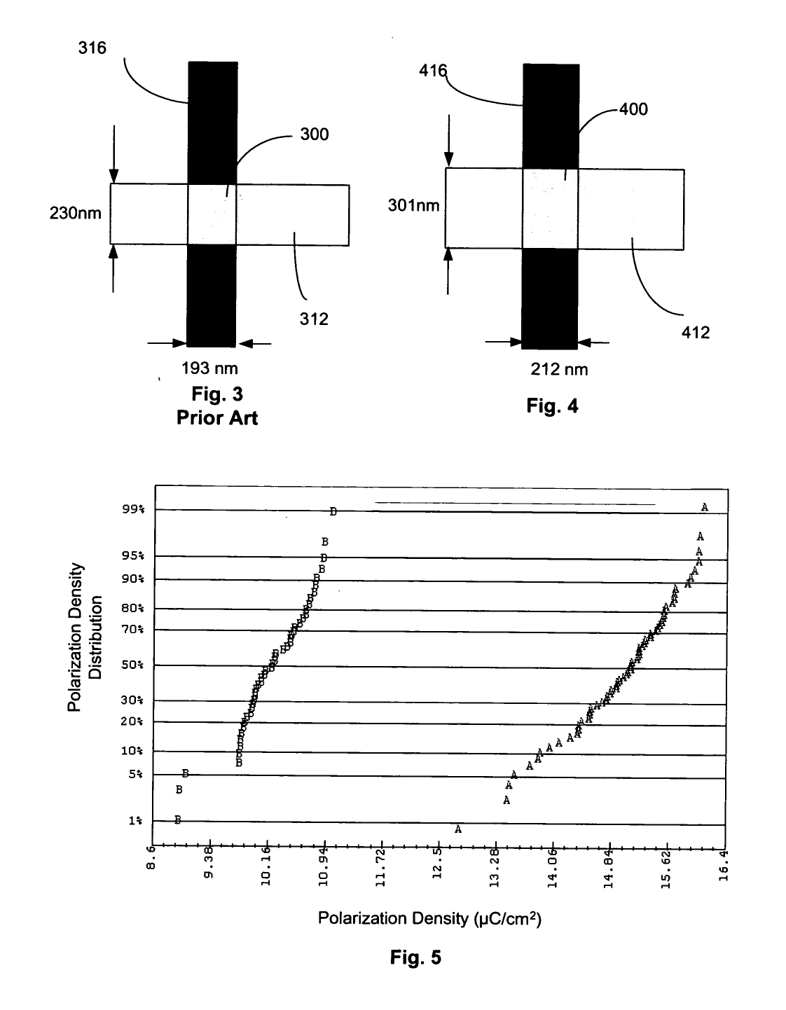

A memory cell according to the prior art and one made according to an embodiment of the present invention (method of fabrication described in further detail below) were compared in terms of their polarization densities. The compared memory cells are shown schematically in top plan view in FIGS. 3 and 4, each of which shows two intersecting electrode layers defining a corresponding memory cell. As seen in FIGS. 3, a memory cell 300 according to the prior art was defined by an intersection of two electrode layers 312 and 316, and as seen in FIG. 4, a memory cell 400 according to a preferred embodiment of the present invention, was defined by an intersection of two electrode layers 412 and 416, there existing a ferroelectric polymer layer (not shown) at such intersections as would be recognized by one skilled in the art. Electrode layers 312 and 316 on the one hand, or electrode layers 412 and 416 were similar to electrode layers 112 and 116, respectively, as depicted in FIG. 1 and described above. The lithography reticle feature size for both the configuration in FIG. 3 and that in FIG. 4 was about 0.25 μm, while the polymeric system included the second ferroelectric polymer layer. As seen in FIG. 3, the prior art cell was associated with a bottom electrode layer having a width of about 230 nm and a top electrode layer having a width of about 193 nm, resulting in a cell area of about 44390 nm². On the other hand, as seen in FIG. 4, a cell according to an embodiment of the present invention was associated with a bottom electrode layer having a width of about 301 nm and a top electrode layer having a width of about 212 nm, resulting in a cell area of about 63812 nm², that is, about 44% larger than the cell size of FIG. 3. The mean polarization density of the configuration of FIG. 3 was experimentally measured to be about 10.23 μC/cm², while that of FIG. 4 was about 14.98 μC/cm², that is, about 46% larger. The above proposes that mean polarization density scales with the cell size.

Referring next to FIG. 5, a plot is provided plotting polarization density distribution (corresponding to the percentage of data points that have a polarization density less than the point plotted) versus polarization density for the memory cell configurations depicted in FIGS. 3 and 4. As clearly seen in FIG. 5, an increase in cell size provides a related increase in polarization density. The ratios of cell area to polarization density for FIGS. 3 and 4 were about 4339.2 and 4259.8, respectively, meaning that about 4300 nm² of cell area would be expected to provide about 1 μC/cm² polarization density for the shown configurations. Based on the above, a predictive method has been developed for evaluating the change in polarization density as a function of electrode profile. The polarization is directly correlated to the capacitance of the structure, and hence to the surface areas of respective ones of the top and bottom electrodes.

Advantageously, embodiments of the present invention replace traditional aluminum etch interconnect structures that employ thick metal and a straight cross sectional profiles having undercuts. Using non-traditional metal etch chemistries as described above, embodiments of the present invention are able to provide thin pyramidal profiles of FPMD electrode layers having rounded corners. All of the above may be achieved according to embodiments with no change to the lithography process used in the prior art. A pyramidal electrode profile according to the present invention may advantageously increase memory cell size, leading to significantly higher polarizations (such as, for example, about 45%), and reduced cross-polymer current leakage without impacting the size of the resultant chip. Being able to obtain more polarization substantially without changing to the materials may be of significant benefit. First, pyramidal profiles according to embodiments of the present invention advantageously improve polymer spin fluid dynamics as the polymer is spun across the electrodes, providing improved planarization and within-array polymer thickness uniformity. The pyramidal profiles may moreover eliminate undercuts. Second, embodiments of the present invention are advantageous in that the corner rounding achieved using TSEP improves polymer leakage, substantially avoiding electric field breakdowns of the polymer found to be associated with sharp corners. Last but not least, a pyramidal profile according to the present invention advantageously increases polymer memory size, and therefore capacitance, which increases polarization density proportionally. The signal strength of the FPMD is directly proportional to the charge density. Starting with higher polarization will provide increased margin for potential polymer degradation and signal loss due to fatigue and disturbance from nearby memory cells.

FIG. 9 is provided to illustrate an example of an application 900 for a ferroelectric device such as FPMD 200 of FIG. 2, in accordance with one embodiment of the claimed subject matter. In this particular embodiment, a device such as device 200 is shown assembled as a memory device 902, which may comprise a structure as shown in FIG. 2, formed by use of the method as described in relation to FIGS. 7 and 8a-8c, for example. Memory device 902 may, for example, be used as a stand alone memory that is used in a portable communication device 912, which may comprise, for example, a mobile communication device (e.g., cell phone), a two-way radio communication system, a one-way pager, a two-way pager, a personal communication system (PCS), a portable computer, or the like. Alternatively, memory device 902 may be used in applications that are not regarded as mobile such as desktop computing systems, although it is important to note that these are exemplary embodiments, and the claimed subject matter is not so limited. Wireless computing device 912 may comprise a processor 904 to execute instructions and comprise a microprocessor, a central processing unit (CPU), a digital signal processor, a microcontroller, a reduced instruction set computer (RISC), a complex instruction set computer (CISC), or the like. Wireless computing device 912 may also optionally include a display 906 to display information to a user, and a transceiver 908 and antenna 910 to provide wireless communication.

It should also be understood that the scope of the claimed subject matter is not limited to stand alone memories. In alternative embodiments, memory device 902 may be formed within or embedded in other components of wireless computing device 912 such as in processor 904. In this embodiment, application 900 may comprise a device 916, which may be capable of receiving transmissions from antenna 910. Transmissions may be transmitted by use of wireless communications media 914, for example. It is important to note, however, that application 900 is an exemplary embodiment of one use of a ferroelectric device in accordance with the claimed subject matter.

It can be appreciated that the embodiments may be applied to the formation of any ferroelectric polymer device. Certain features of the embodiments of the claimed subject matter have been illustrated as described herein, however, many modifications, substitutions, changes and equivalents will now occur to those skilled in the art. Additionally, while several functional blocks and relations between them have been described in detail, it is contemplated by those of skill in the art that several of the operations may be performed without the use of the others, or additional functions or relationships between functions may be established and still be in accordance with the claimed subject matter. It is, therefore, to be understood that the appended claims are intended to cover all such modifications and changes as fall within the true spirit of the embodiments of the claimed subject matter.

What is claimed is:

1. A ferroelectric polymer memory device comprising:
a substrate;
a plurality of electrode layers including a first electrode layer disposed on the substrate and a second electrode layer extending at an angle with respect to the first electrode layer in a longitudinal direction thereof;
a ferroelectric layer disposed between the first electrode layer and the second electrode layer to form memory cells;
an ILD layer disposed on the second electrode layer;
wherein at least one of the plurality of electrode layers exhibits a pyramidal profile in a widthwise cross-section thereof.

2. The device of claim 1, wherein each of the plurality of electrode layers comprises a plurality of electrodes extending in a parallel direction with respect to one another.

3. The device of claim 1, wherein the first electrode layer and the second electrode layer extend perpendicularly with respect to one another in a longitudinal direction thereof.

4. The device of claim 1, wherein the device comprises a plurality of ferroelectric layers alternating with the plurality of electrode layers, each successive one of the plurality of electrode layers extending at an angle with respect to a former one of the plurality of electrode layers a longitudinal direction thereof to form memory cells in conjunction with the ferroelectric layers, the ferroelectric layer being one of the plurality of ferroelectric layers.

5. The device of claim 1, wherein each of the plurality of electrode layers include at least one electrode, the at least one electrode including a plurality of electrode sublayers.

6. The device of claim 5, wherein each of the electrode sublayers has sides including rounded corners as seen in a widthwise cross-section thereof.

7. The device of claim 5, wherein the pyramidal profile does not include any undercuts defined between successive ones of the plurality of electrode sublayers.

8. The device of claim 1, wherein both the first electrode layer and the second electrode layer exhibit a pyramidal profile in a widthwise cross-section thereof.

9. The device of claim 1, wherein the plurality of electrode sublayers includes a first sublayer comprising one of Ti and TiN, a second sublayer comprising Al, and a third sublayer comprising one of Ti and TiN, the second sublayer being disposed between the first sublayer and the second sublayer.

10. A method of providing an electrode layer of a ferroelectric memory device comprising:
providing a structure comprising a conductive layer disposed on a ferroelectric polymer layer; and
forming an electrode layer from the conductive layer, the electrode layer exhibiting a pyramidal profile.

11. The method of claim 10, wherein the conductive layer comprises a first conductive sublayer, a second conductive sublayer and a third conductive sublayer superimposed on one another.

12. The method of claim 11, wherein forming includes:
providing a patterned resist layer on the conductive layer, the resist layer having a plurality of resist legs;
etching the third conductive sublayer to achieve a first configuration of the third conductive sublayer including sides of the third conductive sublayer that are generally sloped from corresponding ones of the resist legs toward the second conductive sublayer, in a direction away from said corresponding ones of the resist legs;
etching the second conductive sublayer to achieve a second configuration of the second conductive sublayer including sides of the second conductive sublayer that are generally sloped from corresponding ones of the sides of the third conductive sublayer toward the first conductive sublayer, in a direction away from said corresponding ones of the sides of the third conductive sublayer; and
etching the first conductive sublayer to achieve a third configuration of the first conductive sublayer includes sides of the first conductive sublayer that are generally sloped from corresponding ones of the sides of the second conductive sublayer toward the ferroelectric layer, the first configuration, the second configuration, and the third configuration together forming an electrode layer exhibiting the pyramidal profile.

13. The method of claim 12, wherein the electrode layer comprises a plurality of electrodes extending in a parallel direction with respect to one another.

14. The method of claim 12, wherein etching the third conductive sublayer comprises using an etch recipe including BCl₃, Cl2 and He.

15. The method of claim 14, wherein the etch recipe includes a BCl₃ flow rate between about 30 to about 60 ccm, a Cl₂ flow rate between about 5 to about 20 ccm, a He flow rate between about 40 to about 100 ccm.

16. The method of claim 12, further comprising exposing the third configuration to a post-etch treatment to substantially prevent corrosion of the second conductive sublayer.

17. The method of claim 16, wherein exposing the third configuration to a post-etch treatment comprises exposing the third configuration to methanol.

18. The method of claim 17, wherein exposing comprises flowing methanol over the first configuration at a flow rate up to about 200 ccm at a temperature below about 140 degrees Centigrade.

19. The method of claim 12, wherein etching the second conductive sublayer comprises using an etch recipe including BCl3 and no Cl2.

20. The method of claim 19, wherein the etch recipe includes a BCl₃ flow rate between about 80 ccm and about 120 ccm.

21. The method of claim 12, wherein etching the first conductive sublayer comprises using an etch recipe including BCl₃, Cl₂ and He.

22. The method of claim 21, wherein the etch recipe includes a BCl₃ flow rate between about 30 to about 60 ccm, a Cl₂ flow rate between about 5 to about 20 ccm, a he flow rate between about 40 to about 100 ccm.

23. A system including a wireless computing device comprising:
ferroelectric polymer memory device comprising:
a substrate;
a plurality of electrode layers including a first electrode layer disposed on the substrate and a second electrode layer extending at an angle with respect to the first electrode layer in a longitudinal direction thereof;
a ferroelectric layer disposed between the first electrode layer and the second electrode layer to form memory cells;
an ILD layer disposed on the second electrode layer;
wherein at least one of the plurality of electrode layers exhibits a pyramidal profile in a widthwise cross-section thereof; and
a microprocessor;
a transceiver; and
an antenna, the memory device, microprocessor, transceiver and antenna being operatively coupled to one another.

24. The system of claim 23, further comprising a display operatively coupled to the memory device, microprocessor, transceiver and antenna.
